(19) United States
(12) Patent Application Publication
(10) Pub. No.: US 2011/0272018 A1
(43) Pub. Date: Nov. 10, 2011

(54) DYE SENSITIZED SOLAR CELL

(75) Inventors: Young Gi LEE, Daejeon (KR); Kwang Man Kim, Daejeon (KR); Kuk Young Cho, Daejeon (KR); Jung Ki Park, Daejeon (KR); Seung Woo Lee, Daejeon (KR); Yong Seok Jun, Ulsan (KR)

(73) Assignee: ELECTRONICS AND TELECOMMUNICATIONS RESEARCH INSTITUTE, Daejeon (KR)

(21) Appl. No.: 13/027,762

(22) Filed: Feb. 15, 2011

(30) Foreign Application Priority Data
May 6, 2010 (KR) 10-2010-0042569

(51) Int. Cl. H01L 31/0232; H01L 31/0224

(52) U.S. Cl. 136/256; 136/259

(57) ABSTRACT

Provided is a dye-sensitized solar cell (DSC). The DSC including a working electrode and a counter electrode facing the working electrode includes a polymer film having a mirror reflection characteristic and attached to the outside of the counter electrode. Since the polymer film having a mirror reflection characteristic is employed, use of light can be increased, and incident photon-to-current conversion efficiency (IPCE) can be improved.

### CROSS-REFERENCE TO RELATED APPLICATION

This application claims priority to and the benefit of Korean Patent Application No. 10-2010-0042569, filed May 6, 2010, the disclosure of which is incorporated herein by reference in its entirety.

### BACKGROUND

1. Field of the Invention

The present invention relates to a dye-sensitized solar cell (DSC), and more particularly to a DSC in which a polymer film having a mirror reflection characteristic is attached to the rear side of a counter electrode to improve power conversion efficiency.

2. Discussion of Related Art

Lately, various kinds of energies for replacing fossil fuels have been researched in order to reduce the amount of carbon dioxide, which is regarded as the main culprit of global warming, and solve the emerging problem of energy. In particular, research for making use of natural energies such as wind power, nuclear power, and sunlight is extensively under way. Among these natural energies, a solar cell using solar energy has great advantages in that it is eco-friendly and can be used almost unlimited.

Currently, silicon solar cells are commercialized. However, silicon solar cells require relatively high production cost owing to the use of silicon material which is also widely used in semiconductors production. Thus, DSCs which is cost competitive are attracting attention in solar cell field.

Meanwhile, lower efficiency of solar energy conversion of DSC should be improved for the extensive utilization.

DSCs generate electron-hole pairs by absorbing visible light energy. DSC is generally consist of a nanoporous TiO₂ photoanode with a ruthenium complex based dye, a Pt counter electrode and an electrolyte with redox couple. A typical DSC using titanium dioxide nanoparticles was developed by Michael Gratzel project team of Ecole Polytechnique Federale de Lausanne (EPFL) in 1991.

Photoelectric current conversion efficiency is proportional to the amount of electrons generated by absorbing sunlight. To increase the efficiency of a solar cell, the amount of generated electrons may be increased by increasing the amount of absorbed sunlight or the amount of absorbed dye, or disappearance of excited electrons caused by electron-hole recombination may be prevented. The reflection efficiency of a platinum electrode may be increased to increase the amount of absorbed sunlight, or oxide semiconductor particles may be produced on a nanometer scale to increase the amount of dye absorbed per unit area. Also, a method of mixing semiconductor oxide light-scatterers having a size of several micrometers, and the like have been developed.

However, conventional methods showed limitation in improving the photoelectric conversion efficiency of a solar cell, and new technology is required to improve the efficiency.

### SUMMARY OF THE INVENTION

The present invention is directed to provide a dye-sensitized solar cell (DSC) whose photoelectric conversion efficiency is improved by employing a polymer film having an excellent mirror reflection characteristic and flexibility.

One aspect of the present invention provides a DSC including a working electrode, a counter electrode facing the working electrode, and also a polymer film having a mirror reflection characteristic and attached onto the exterior of the counter electrode.

The polymer film having a mirror reflection characteristic may be a complex layer formed by repeatedly stacking two materials having different refractive indices, may have a refractive index of 97% or more in the visible light region, may have flexible under bending stress. The example of the polymer film having a mirror reflection characteristic is Enhanced Specular Reflector (ESR) available from 3M.

The working electrode may be a conductive substrate on which a metal oxide particle layer is coated, and the counter electrode may be a conductive substrate on which a catalyst layer is coated.

The polymer film having a mirror reflection characteristic may be attached in at least the same size as an active area of the counter electrode, or in greater size than the active area of the counter electrode.

The polymer film having a mirror reflection characteristic may be attached to the rear side of the counter electrode avoiding any scratch on the surface of the polymeric mirror.

### BRIEF DESCRIPTION OF THE DRAWINGS

The above and other objects, features and advantages of the present invention will become more apparent to those of ordinary skill in the art by describing in detail exemplary embodiments thereof with reference to the attached drawings, in which:

FIG. 1 is a cross-sectional view of a dye-sensitized solar cell (DSC) according to an exemplary embodiment of the present invention;

FIG. 2 illustrates cases in which light passed through a DSC according to conventional art is discarded, and light is reflected without being passed through a DSC according to an exemplary embodiment of the present invention; and

FIG. 3 is a graph showing results of measuring incident photon-to-current conversion efficiency (IPCE) of a solar cell according to an exemplary embodiment of the present invention.

### DETAILED DESCRIPTION OF EXEMPLARY EMBODIMENTS

Hereinafter, exemplary embodiments of the present invention will be described in detail. However, the present invention is not limited to the embodiments disclosed below but can be implemented in various forms. The following embodiments are described in order to enable those of ordinary skill in the art to embody and practice the present invention. To clearly describe the present invention, parts not relating to the description are omitted from the drawings. Like numerals refer to like elements throughout the description of the drawings.

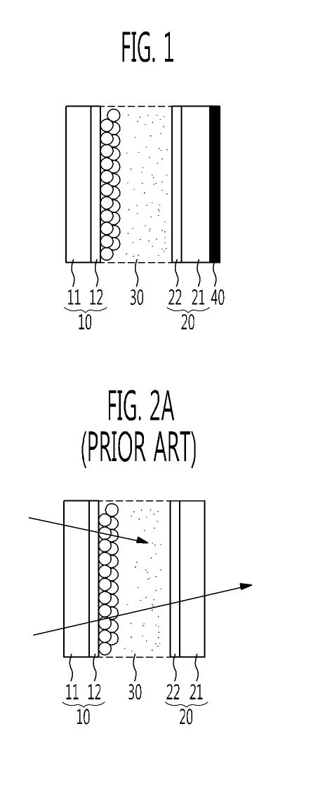

FIG. 1 is a cross-sectional view of a dye-sensitized solar cell (DSC) according to a first exemplary embodiment of the present invention.

Referring to FIG. 1, a DSC 100 according to an exemplary embodiment of the present invention includes a working electrode 10, a counter electrode 20 facing the working electrode 10, an electrolyte 30 between the working electrode 10 and the counter electrode 20, and a polymer film 40 having a mirror reflection characteristic and attached to the outside of the counter electrode 20. Light passed through an active area of the DSC 100 is reflected and reused, and light discarded to an area other than the active area is also reflected, thereby improving photoelectric conversion efficiency.

In the working electrode 10 constituting the DSC 100 according to an exemplary embodiment of the present invention, a metal oxide particle layer 12 is formed on a conductive substrate 11, and dye is absorbed on the metal oxide particle layer 12.

As the conductive substrate 11, a substrate generally used in this field can be used. For example, a transparent substrate such as glass, a conductive metal substrate, a semiconductor substrate, a non-conductive substrate, etc. can be used.

The metal oxide particle layer 12 is formed by coating a paste including metal oxide nanoparticles and annealing it. In this case, titanium dioxide, tin dioxide, zinc oxide, etc. may be used as the metal oxide, but the metal oxide is not limited to these materials. Dye molecules are absorbed on the metal oxide particle layer 12, and general dye molecules in this field can be used.

When the metal oxide particle layer 12 is formed on the conductive substrate 11 of the working electrode 10, a metal oxide precursor or nanoparticles are coated and annealed to improve adhesion, and a blocking layer may be additionally formed to prevent electrons generated by hindering recombination from moving in the reverse direction and increase efficiency.

The counter electrode 20 constituting the DSC 100 according to an exemplary embodiment of the present invention faces the working electrode 10, and is fabricated by forming a catalyst layer 22 on a conductive substrate 21. Platinum, etc. may be used for the catalyst layer 22, but the catalyst layer 22 is not limited to platinum.

As the conductive substrate 21, a substrate generally used in this field can be used. Like the working electrode 10, a transparent substrate such as glass, a conductive metal substrate, a semiconductor substrate, a non-conductive substrate, etc. can be used.

The working electrode 10 and the counter electrode 20 are attached to each other face to face using a general method in this field, thereby forming a sandwich cell. For example, a seal tape is disposed between the working electrode 10 and the counter electrode 20, and then the two electrodes are closely adhered. At this time, heat and pressure are applied so that the seal tape can be strongly adhered to the surfaces of the two electrodes. As the seal tape, a general seal tape in this field can be used.

An electrolyte 30 is injected between the working electrode 10 and the counter electrode 20. At this time, a general type of electrolyte and a general method in this field can be used.

The polymer film 40 having a mirror reflection characteristic and attached to the outside of the counter electrode 20 is a complex layer formed by repeatedly stacking two materials having different refractive indices. The polymer film 40 has flexibility and a refractive index of 97% or more in the visible light region.

The polymer film 40 having a mirror reflection characteristic is a complex layer in which refractive indices in a Z direction are matched. For example, in the complex layer, polymethylmethacrylate (PMMA) and polyethylene naphthalate (PEN) are repeatedly stacked 100 times or more. In this case, the thickness of the complex layer is λ/4n. Thus, the complex layer operates as an effective one-dimensional photonic crystal and has the maximum refractive index at a wavelength of λ.

Such a polymer film has mirror reflection rather than diffuse reflection. Thus, reflection efficiency of the polymer film having mirror reflection deteriorates little according to a change in incidence angle, and the polymer film can reflect light of a variety of incidence angles with high efficiency.

A typical commercialized product of a polymer film having a mirror reflection characteristic is Enhanced Specular Reflector (ESR) available from 3M.

In comparison with a metal reflection layer, the polymer film 40 having a mirror reflection characteristic has relatively high intensity of reflected light in spite of high reflection efficiency and a wide range of the incidence angle. Also, the polymer film 40 has flexibility and can be easily attached to a counter electrode of a DSC.

The polymer film 40 having a mirror reflection characteristic may be attached in at least the same size as an active area of the counter electrode 20, or a greater size than the active area of the counter electrode 20. The polymer film 40 should have at least the size of the active area to reuse light coming through the active area, and most preferably, is attached to an entire surface. When the polymer film 40 is attached to the rear side of the counter electrode 20, the polymer film 40 is easily attached to the entire rear side, and most preferably, covers the entire rear side. Meanwhile, the polymer film 40 should have multiple stacked layers to have a reflection efficiency of 98% or more and thus has a thickness of 40 microns or more. For flexibility, the polymer film 40 may have a thickness of 250 microns or less.

The polymer film 40 should be attached to the rear side of the counter electrode 20 with no flaw, more specifically, no scratch made on the film surface. A scratch may severely deteriorate a reflection characteristic. Thus, any methods can be used to prevent a scratch from being formed by the polymer film 40 pushed left, right, up and down when the polymer film 40 is attached to the rear side of the counter electrode 20. However, an adhesive or tape cannot be used between the polymer film 40 and the counter electrode 20. The edge of the counter electrode 20 and the polymer film 40 may be fixed by an adhesive or tape.

FIG. 2 shows a general DSC according to conventional art (a) through which light is passed and discarded, and a DSC according to an exemplary embodiment of the present invention (b) in which a polymer film having a mirror reflection characteristic is attached to the rear side of a counter electrode and reflects light passed through the DSC to be discarded. As illustrated in FIG. 2, the DSC according to an exemplary embodiment of the present invention can remarkably improve photoelectric conversion efficiency by reusing light passed through the DSC itself to be discarded.

Exemplary embodiments of the present invention will be described in further detail below. However, the embodiments are merely examples of the present invention, and the present invention is not limited to the embodiments.

### Exemplary Embodiment 1

### (1) Fabrication of Working Electrode

After conductive glass coated with fluorine-doped tin oxide (FTO) (Pilkington, TEC 7) was cut off in a size of 1.5 cm×1.5 cm and underwent ultrasonic cleaning with soapy water for five minutes, the soapy water was completely removed. After this, ultrasonic cleaning with ethanol was repeated three times for five minutes. Subsequently, the FTO glass was completely rinsed with absolute ethanol and then dried in an oven. To increase adhesion to TiO₂, the resultant FTO glass was spin-coated with 0.2 M titanium (IV) butoxide solution and completely dried in an oven. The resultant FTO glass was coated with titania using a Dr. Blade and then dried at 100° C. for ten minutes. After this, the resultant FTO glass was annealed at 450° C. to obtain a TiO₂ film having a thickness of 10 μm. The electrode fabricated in this way was put in a dye solution mixed with absolute ethanol at a concentration of 0.5 mM and left for 24 hours to absorb dye. In this embodiment, N719 dye was used.

### (2) Fabrication of Counter Electrode

Two holes through which electrolyte would be injected were formed in an FTO glass having a size of 1.5 cm×1.5 cm using a diamond drill (Bosch, Dremel multipro395). After this, cleaning and drying were performed, like in the fabrication of the working electrode. The resultant FTO glass was coated with hydrogen hexachloroplatinate/2-propanol (H₂PtCl₆) solution and then annealed at 450° C. for 30 minutes.

### (3) Fabrication of Sandwich Cell

Surlyn cut in a rectangular band shape (Solaronix, SX1170-25 Hot melt) was placed between the working electrode and the counter electrode. After the two electrodes were attached to each other using a hot press, electrolyte was injected through the two small holes of the counter electrode, and then the holes were sealed by a Surlyn strip and cover glass to fabricate a sandwich cell. The electrolyte solution was obtained by dissolving 0.1 M LiI, 0.05 M I₂, and 0.5 M 4-tert-butylpyridine in 3-methoxypropionitrile. In the fabricated cell, an active area was 4.0 mm×4.0 mm (width×length).

(4) On the outside of the counter electrode of the fabricated sandwich cell, as a polymer film having a mirror reflection characteristic, ESR from 3M was cut to have the same area as the counter electrode and attached in the same size as an active area of the counter electrode.

### Exemplary Embodiment 2

A DSC was manufactured to be the same as Exemplary embodiment 1 except that a polymer film having a mirror reflection characteristic was attached to the outside of a counter electrode in a size of 1.5 cm×1.5 cm (width×length) (i.e., attached to an entire surface of the counter electrode), which is larger than an active area.

### Comparative Example 1

A DSC was manufactured to be the same as Exemplary embodiment 1 except that a polymer film having a mirror reflection characteristic was not attached.

### Comparative Example 2

A DSC was manufactured to be the same as Exemplary embodiment 1 except that an aluminum foil was attached instead of a polymer film having a mirror reflection characteristic.

### Experimental Example

### Energy Conversion Efficiency

The DSCs manufactured according to Exemplary Embodiments 1 and 2 and Comparative Examples 1 and 2 were illuminated by a Xe lamp (Oriel, 300 W Xe arc lamp) with an AM 1.5 solar simulating filter, and a current-voltage curve was obtained using an M236 source measure unit (SMU, Keithley). Electric potential had a range from −0.8 V to 0.2 V, and light had intensity of 100 mW/cm². In this way, energy conversion efficiency was measured. Fill factors were calculated using the conversion efficiency and a formula below, and the results are shown in Table 1.

Fill factor (%)=((J×V)ₘₐₓ/(J_{sc}×V_{oc}))×100 Formula

In the formula above, J denotes a Y-axis value of the conversion efficiency curve, V denotes an X-axis value of the conversion efficiency curve, and J_{sc} and V_{oc} are intercepts of the respective axes.

TABLE 1

| | Exemplary | Exemplary | | |
|---|---|---|---|---|
| | Embodiment | Embodiment | Comparative | Comparative |
| | 1 | 2 | Example 1 | Example 2 |
| Energy | 7.8 | 9.9 | 7.0 | 7.5 |
| Conversion | | | | |
| Efficiency (%) | | | | |
| Increase in | 11.1 | 41.4 | 0 | 7.1 |
| Efficiency | | | | |
| Relative to | | | | |
| Comparative | | | | |
| Example 1 (%) | | | | |

Incident Photon-to-Current Conversion Efficiency (IPCE)

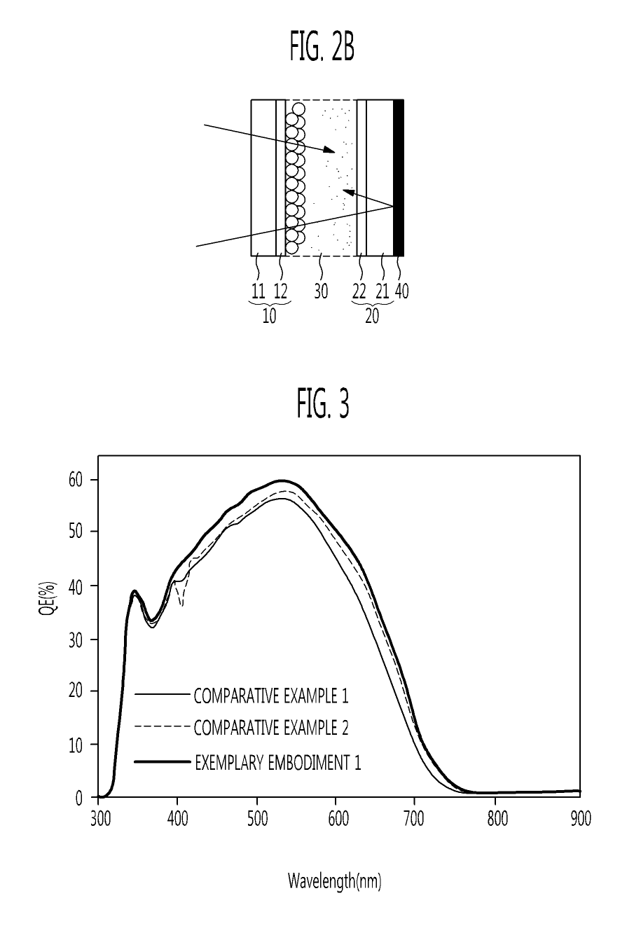

IPCEs of the DSCs manufactured according to Exemplary Embodiments 1 and 2 and Comparative Examples 1 and 2 were measured, and the results are shown in FIG. 3. An IPCE is calculated by dividing the number of electrons generated by light in an external circuit by the number of photons incident at a specific wavelength. The IPCEs were measured using a spectral sensitivity analysis system. The measurement was performed in a wavelength range from 300 to 900 nm.

From the energy conversion efficiencies and IPCEs, it was confirmed that a DSC in which a polymer film having a mirror reflection characteristic is attached to the outside of a counter electrode (i.e., Exemplary Embodiments 1 and 2) has higher energy conversion efficiency than a DSC alone. Even when a metal reflection film such as an aluminum foil is used (i.e., Comparative Example 2), energy conversion efficiency increases, but only slightly. When the metal reflection film is attached to a large surface, close adhesion is difficult, and wrinkles are formed because the metal reflection film is not restored to its original state. In other words, a metal reflection film is difficult to apply. On the other hand, since a polymer film having a mirror reflection characteristic applied to Exemplary Embodiments 1 and 2 has flexibility, it can be easily attached to the outside of a counter electrode without wrinkles, and Exemplary Embodiments 1 and 2 have higher energy conversion efficiencies and IPCEs than Comparative Examples 1 and 2.

Also, when the attachment area of the polymer film having a mirror reflection characteristic is increased beyond an active area as in Exemplary Embodiment 2, discarded light as well as light passed through the active area is reflected, and energy conversion efficiency is remarkably improved. In particular, the decrease of light intensity reflected by a polymer mirror according to an incidence angle is much less than that of a metal reflection film such as an aluminum foil.

As described above, a DSC manufactured by attaching a polymer film having a mirror reflection characteristic to the outside of a counter electrode according to an exemplary embodiment of the present invention can easily reuse light passed through the DSC to be discarded, and thus can have remarkably improved photoelectric conversion efficiency.

The polymer film having a mirror reflection characteristic and employed in the DSC according to an exemplary embodiment of the present invention has flexibility and thus can be easily applied to a curved surface. Also, the polymer film has a high refractive index regardless of an incidence angle in the entire visible-light region, thus minimizing passed and discarded light and having high efficiency and little influence from solar altitude.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A dye-sensitized solar cell (DSC) including a working electrode and a counter electrode facing the working electrode, comprising:
a polymer film having a mirror reflection characteristic and attached onto the exterior of the counter electrode.

2. The DSC of claim 1, wherein the polymer film having a mirror reflection characteristic is a complex layer formed by repeatedly stacking two materials having different refractive indices.

3. The DSC of claim 1, wherein the polymer film having a mirror reflection characteristic has a reflective index of exceeding 97% in a visible light region.

4. The DSC of claim 1, wherein the polymer film having a mirror reflection is flexible under bending stress.

5. The DSC of claim 1, wherein the polymer film having a mirror reflection characteristic is Enhanced Specular Reflector (ESR) available from 3M.

6. The DSC of claim 1, wherein the working electrode is a conductive substrate coated with a metal oxide particle layer.

7. The DSC of claim 1, wherein the counter electrode is a conductive substrate coated with a catalyst layer.

8. The DSC of claim 1, wherein the polymer film having a mirror reflection characteristic is attached in at least the same size as an active area of the counter electrode.

9. The DSC of claim 1, wherein the polymer film having a mirror reflection characteristic is attached in greater size than an active area of the counter electrode.

10. The DSC of claim 1, wherein the polymer film having a mirror reflection characteristic is attached to a rear side of the counter electrode with no flaw.
